(19) United States
(12) Patent Application Publication
(10) Pub. No.: US 2026/0246427 A1
(43) Pub. Date: Aug. 20, 2026

(54) METHOD AND DEVICES TO INCREASE POWER ADDED EFFICIENCY IN POWER AMPLIFIERS

(71) Applicant: pSemi Corporation, San Diego, CA (US)

(72) Inventors: Lei MA, SAN DIEGO, CA (US); Jon KUJANSKI, SAN DIEGO, CA (US)

(21) Appl. No.: 19/055,318

(22) Filed: Feb. 17, 2025

(51) Int. Cl. H03F 1/02; H03F 1/56; H03F 3/24; H03F 3/30; H03F 3/45

(52) U.S. Cl. CPC H03F 1/0288; H03F 1/565; H03F 3/245; H03F 3/3076; H03F 3/45475

(57) ABSTRACT

Methods and devices for improving power added efficiency in multi-stage power amplifiers. The disclosed techniques implement harmonic termination at the driver amplifier while accounting for parasitic elements. The described teachings improve power added efficiency, enhance reliability through reduced peak voltages, and maintain or improve linearity. The techniques are effective at higher operating frequencies and can be applied to both single-ended and differential amplifier architectures. In one embodiment, a multi-stage power amplifier system includes a driver amplifier (DA) stage coupled through an interstage matching network to a power amplifier stage. A DA harmonic termination circuit provides an approximate short circuit at second harmonic frequencies and an approximate open circuit at third harmonic frequencies. The DA harmonic termination circuit includes capacitive and inductive components that work in conjunction with the parasitic output capacitance and series inductance of the DA to increase the overall PAE of the system.

### TECHNICAL FIELD

This invention relates to power amplifiers, and more particularly to methods and devices for increasing power added efficiency (PAE) in multi-stage power amplifiers.

### BACKGROUND

Power Amplifiers (PAs) are essential elements in radio frequency (RF) front-end (RFFE) circuits used in RF systems such as cellular base stations and WiFi networks, with particularly high application demands in consumer premises equipment (CPE) and cellular infrastructure. The primary function of PAs is to amplify signals while adhering to stringent performance requirements, including gain, output power, and linearity. Significant efforts have been made to enhance the Power Added Efficiency (PAE) of PAs, a critical parameter for minimizing power consumption and heat dissipation. More specifically, PAE is a metric for rating the efficiency of a power amplifier that takes into account the effect of the gain of the amplifier.

Conventional two-stage linear PA architectures utilize a driver amplifier (DA) for gain compression and a PA for gain expansion. This configuration is designed to optimize PAE and linearity with harmonic management techniques, such as a class F termination employed at the PA stage. Class F termination, which employs harmonic impedance tuning (e.g., second harmonic short and third harmonic open), enhances efficiency by minimizing the overlap between voltage and current waveforms. Despite these developments, current approaches remain constrained, with the benefits of class F termination applied only at the PA stage.

There is a need for innovative methods to further enhance PAE in linear PA designs while maintaining other critical RF performance metrics, addressing the limitations of existing techniques.

### SUMMARY

The present invention encompasses methods and devices for increasing power added efficiency in multi-stage power amplifiers through implementation of harmonic termination at the driver amplifier stage. The disclosed techniques account for parasitic elements of the amplifier in the design of the harmonic termination circuit to achieve better impedance matches at harmonic frequencies.

In one embodiment, a power amplifier system includes a driver amplifier (DA) coupled through an interstage matching network to a power amplifier (PA). A harmonic termination circuit coupled to the output of the DA provides specific impedances at harmonic frequencies, particularly providing an approximate short circuit at second harmonic frequencies and an approximate open circuit at third harmonic frequencies. The harmonic termination circuit includes capacitive and inductive components that work in conjunction with the parasitic output capacitance and series inductance of the DA to increase overall PAE of a multi-stage power amplifier.

The disclosed circuits and techniques provide several advantages, including improved power added efficiency, reduced peak voltages on the driver transistors leading to enhanced reliability, and maintained or improved linearity. The effectiveness of the driver stage harmonic termination is particularly beneficial at higher operating frequencies where the required component values are more readily achievable, particularly in integrated circuit (IC) embodiments.

While demonstrated in the context of a differential power amplifier architecture, the disclosed teachings apply equally to single-ended designs. The described methods can also be extended to multi-stage amplifier topologies including three or more stages.

The details of one or more embodiments of the invention are set forth in the accompanying drawings and the description below. Other features, objects, and advantages of the invention should be apparent from the description and drawings, and from the claims.

According to a first aspect of the present disclosure, a power amplifier system is provided including a) a driver amplifier; b) a power amplifier coupled to an output of the driver amplifier, and c) a first harmonic termination circuit coupled to the output of the driver amplifier, wherein the first harmonic termination circuit is configured to provide a low impedance at second harmonic frequencies and a high impedance at third harmonic frequencies based on parasitic elements of the driver amplifier.

According to a second aspect of the present disclosure, a wireless communication device is provided, including a radio frequency front end module including: a multi-stage power amplifier including a) a driver amplifier, b) a power amplifier coupled to an output of the driver amplifier; and c) a driver harmonic termination circuit coupled to the output of the driver amplifier, wherein the driver harmonic termination circuit is configured to provide a low impedance at second harmonic frequencies and a high impedance at third harmonic frequencies based on parasitic elements of the driver amplifier.

According to a third aspect of the present disclosure, a power amplifier system is provided, including a plurality of cascaded amplifier stages including a) at least one driver stage, b) a power stage, and a) a plurality of harmonic termination circuits, each coupled to an output of a respective amplifier stage, wherein each harmonic termination circuit is configured to provide stage-specific harmonic impedances based on parasitic elements of its respective amplifier stage.

According to a fourth aspect of the present disclosure, a method of improving power-added efficiency in a multi-stage amplifier is described, the method including: receiving an input signal at a driver amplifier; amplifying the input signal at the driver amplifier; forming, via a harmonic termination circuit disposed at an output of the driver amplifier: a) a low impedance to second harmonic frequencies, and b) a high impedance to third harmonic frequencies; coupling the amplified signal from the driver amplifier to a power amplifier, and amplifying the coupled amplified signal at the power amplifier to generate an output signal.

### DESCRIPTION OF THE DRAWINGS

FIG. 1A shows a block diagram of an exemplary two-stage power amplifier system according to an embodiment of the present disclosure.

FIG. 1B shows a block diagram of an exemplary multi-stage power amplifier system according to an embodiment of the present disclosure.

FIG. 2A shows an exemplary implementation of the power amplifier system of FIG. 1A according to an embodiment of the present disclosure.

FIG. 2B shows parasitic elements that impact the performance of the embodiment of FIG. 2A.

FIG. 3 shows power added efficiency versus output power characteristics before inclusion of a DA harmonic termination circuit in the two-stage PA system of FIG. 1A.

FIG. 4 shows power added efficiency versus output power characteristics after inclusion of a DA harmonic termination circuit in the two-stage PA system of FIG. 1A.

FIG. 5A-5B show Smith chart plots characterizing the interstage matching network without the inclusion of the DA harmonic termination circuit on the output of the DA, within a frequency range of 10 MHz to 20 GHz.

FIG. 6A-6B show Smith chart plots characterizing the interstage matching network with the inclusion of the DA harmonic termination circuit on the output of the DA, within a frequency range of 10 MHz to 20 GHz.

FIG. 7 is a graph showing the frequency response characteristics (S21) of the interstage matching network (104) without the inclusion of the DA harmonic termination circuit (120) on the output of the DA.

FIG. 8 is a graph showing the frequency response characteristics (S21) of the interstage matching network with the inclusion of the DA harmonic termination circuit on the output of the DA.

FIG. 9 is a graph showing the voltage waveform measured at the collector of the DA transistor implemented in one embodiment of an exemplary two-stage PA system that lacks a DA harmonic termination circuit.

FIG. 10 is a graph showing a modified voltage waveform measured at the collector of the DA transistor implemented in one embodiment of an exemplary two-stage PA system that includes a DA harmonic termination circuit.

FIG. 11 is a graph of Error Vector Magnitude (EVM) performance versus power output P_{OUT} without inclusion of a DA harmonic termination circuit on the output of a DA.

FIG. 12 is a graph of Error Vector Magnitude (EVM) performance versus power output P_{OUT} with inclusion of a DA harmonic termination circuit on the output of a DA.

FIG. 13 shows an exemplary flowchart illustrating a method of power-added efficiency improvement in multi-stage amplifier systems according to an embodiment of the present disclosure.

FIG. 14 is a top plan view of a substrate that may be, for example, a printed circuit board or chip module substrate (e.g., a thin-film tile).

FIG. 15 illustrates a prior art wireless communication environment including different wireless communication systems, and which may include one or more mobile wireless devices.

FIG. 16 is a block diagram of a transceiver that might be used in a wireless device, such as a cellular telephone, and which may beneficially incorporate an embodiment of the present invention for improved performance.

Like reference numbers and designations in the various drawings indicate like elements unless the context requires otherwise.

### DETAILED DESCRIPTION

The present invention encompasses methods and devices for increasing power added efficiency in multi-stage power amplifiers through implementation of harmonic termination at the driver amplifier stage. The disclosed techniques account for parasitic elements of the amplifier in the design of the harmonic termination circuit to achieve better impedance matches at harmonic frequencies.

In one embodiment, a power amplifier system includes a driver amplifier (DA) coupled through an interstage matching network to a power amplifier (PA). A harmonic termination circuit coupled to the output of the DA provides specific impedances at harmonic frequencies, particularly providing an approximate short circuit at second harmonic frequencies and an approximate open circuit at third harmonic frequencies. The harmonic termination circuit includes capacitive and inductive components that work in conjunction with the parasitic output capacitance and series inductance of the DA to increase overall PAE of a multi-stage power amplifier.

The disclosed circuits and techniques provide several advantages, including improved power added efficiency, reduced peak voltages on the driver transistors leading to enhanced reliability, and maintained or improved linearity. The effectiveness of the driver stage harmonic termination is particularly beneficial at higher operating frequencies where the required component values are more readily achievable, particularly in integrated circuit (IC) embodiments.

While demonstrated in the context of a differential power amplifier architecture, the disclosed teachings apply equally to single-ended designs. The described methods can also be extended to multi-stage amplifier topologies including three or more stages.

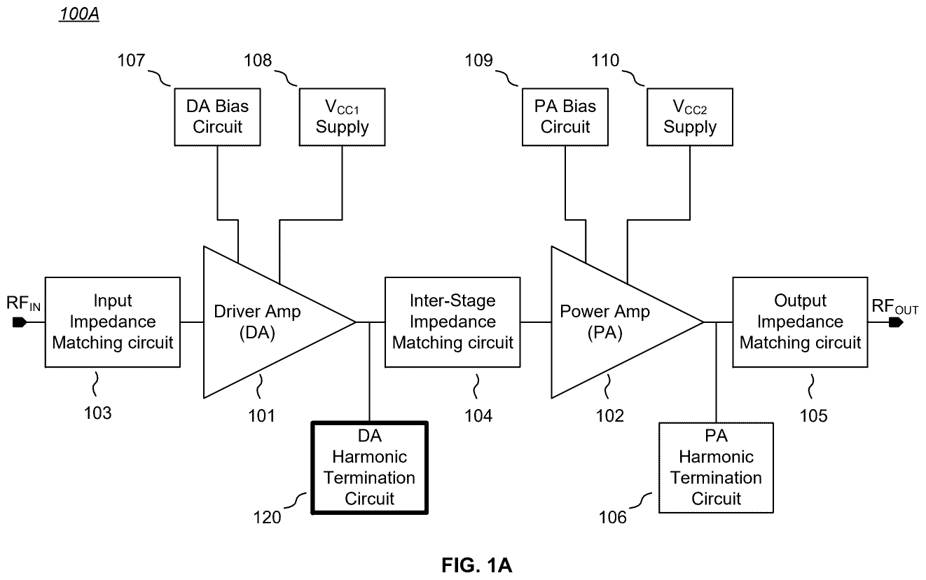

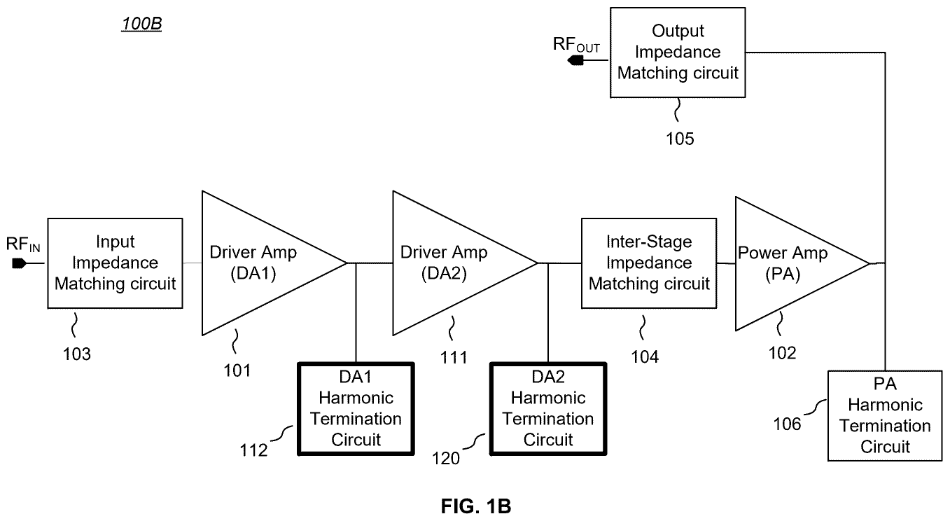

FIG. 1A shows a block diagram of an exemplary two-stage PA system 100A according to an embodiment of the present disclosure. PA system 100A includes an input impedance matching circuit 103, a DA 101, an interstage impedance matching circuit 104, a PA 102, and an output impedance matching circuit 105. In operational conditions, an RF input signal RF_{IN} is received by the input matching circuit 103. This matched signal is then fed into DA 101 to boost the signal strength. The output of DA 101 connects to the PA 102 for further signal amplification. The amplified signal passes through the output matching circuit to produce the RF output signal RF_{OUT}. A DA bias circuit 107 and first power supply 108 provide biasing and a voltage V_{CC1} for DA 101. Similarly, a PA bias circuit 109 and second power supply 110 provide biasing and a voltage V_{CC2} for PA 102.

The power amplifier system of FIG. 1A further includes a PA harmonic termination circuit 106 coupled to the output of PA 102. In a departure from accepted practice, embodiments of the present invention include a DA harmonic termination circuit 120, which provides the unique benefits described below.

According to the teachings of the present disclosure, DA 101 operates in gain compression while the PA 102 operates in gain expansion to achieve amplitude modulation to amplitude modulation (AM-AM) and amplitude modulation to phase modulation (AM-PM) distortion cancellation between stages. The DA and PA harmonic termination circuits 120, 106 are designed to present specific impedances at harmonic frequencies. In a preferred embodiment, the DA harmonic termination circuit 120 implements class F operation by presenting an approximately short circuit (low impedance) at second harmonic frequencies and an approximately open circuit (high impedance) at third harmonic frequencies at the output of the DA 101. Note that in some embodiments, the PA harmonic termination circuit 106 at the output of the PA is optional. In other words, some embodiments may include only the DA termination circuit 120, while others may incorporate both the DA and PA harmonic termination circuits 120, 106. As will be explained more in detail throughout the document, adding the DA harmonic termination circuit 120 at the DA output enhances the PAE of the PA system 100 while preserving key RF performance metrics like gain, power, and linearity. Including the conventional PA harmonic termination circuit 106 at the PA output further enhances the PAE of the PA system 100. The combination of the DA and PA harmonic termination circuits 120, 106 provides a significant improvement in PAE compared to a PA system that includes only a PA harmonic termination circuit 106.

Driver amplifiers may also be implemented in multi-stage configurations. FIG. 1B shows a block diagram of an exemplary multi-stage PA system 100B according to an embodiment of the present disclosure. The overall functionality of the multi-stage PA system 100B is similar to that of the two-stage amplifier 100A depicted in FIG. 1A. However, in the multi-stage amplifier 100B, the driver amplifier includes two stages: DA1 101 and DA2 111, each with its respective harmonic termination circuits 112, 120. It should be clear that in embodiments utilizing one or more driver amplifier stages, any of these stages may incorporate a DA harmonic termination circuit.

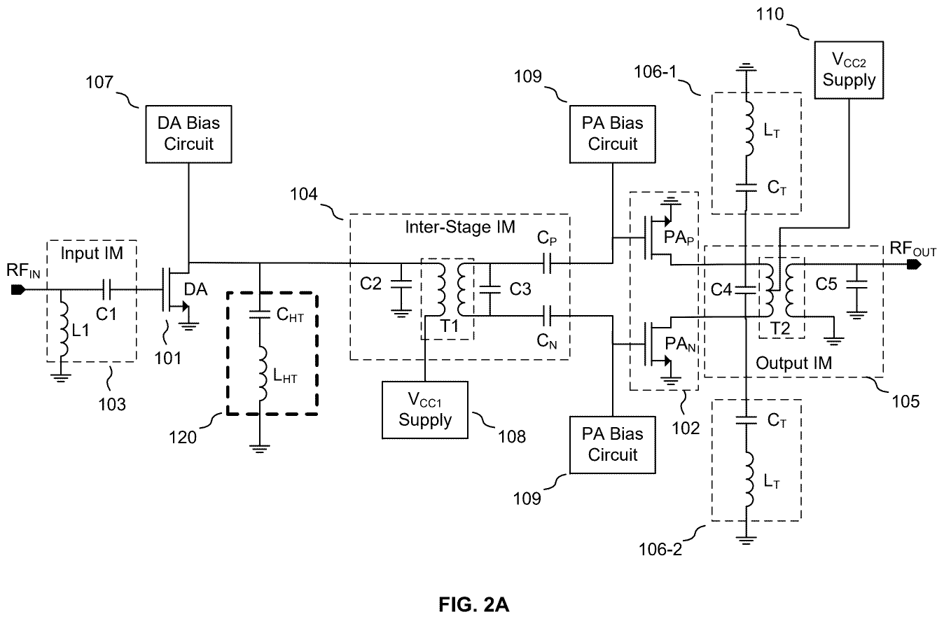

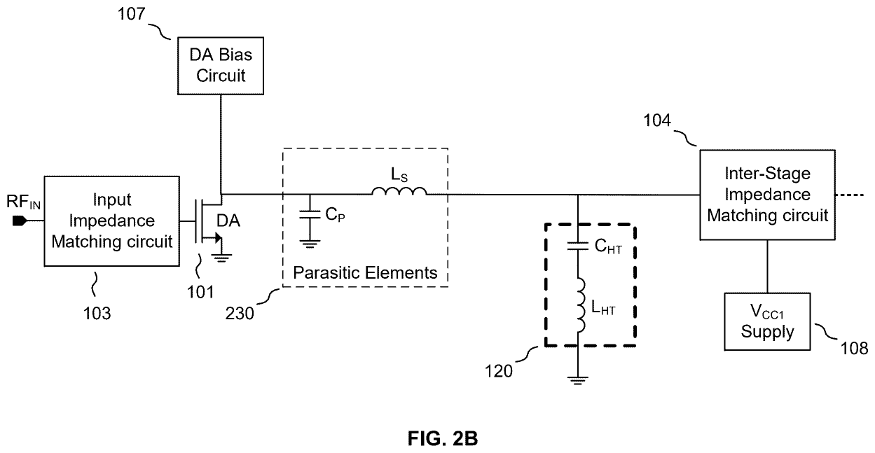

FIG. 2A shows an exemplary implementation of the power amplifier system 100A of FIG. 1A according to an embodiment of the present disclosure. In the illustrated example, the input impedance matching circuit 103 includes an inductor L1 and capacitor C1. The DA harmonic termination circuit 120 includes a capacitor C_{HT} coupled in series with an inductor L_{HT} (note that the order of C_{HT} and L_{HT} may be reversed). The illustrated DA 101 includes a FET transistor configured in a single-ended configuration, while the illustrated PA 102 includes a pair of FET transistors PA_{P}, PA_{N} configured in a differential topology. The differential design of the PA 102 requires two PA harmonic termination circuits 106-1, 106-2, each containing a capacitor C_{T} and inductor L_{T} in series. The illustrated interstage matching circuit 104 contains capacitors C2, C3 alongside transformer T1, where transformer T1 includes a primary winding coupled to the output of DA 101, and a center-tapped secondary winding coupled to differential inputs of PA 102. Transformer T1 performs the single-ended to differential conversion. The output matching circuit 105 includes capacitors C4, C5, and transformer T2 for differential to single-ended conversion. As should be clear, other circuit configurations may be used for the illustrated impedance matching circuits, the differential to single-ended conversion circuitry, and the single-ended to differential conversion circuitry.

FIG. 2B highlights key parasitic elements that impact the performance of the embodiment of FIG. 2A. Parasitic element 230 includes the output parallel capacitance C_{P} of the DA 101 and the series parasitic inductance L_{S} that results from the one or more conductors (e.g., metal traces) connecting the DA 101 to the interstage impedance matching network 104. The DA harmonic termination circuit 120 with components C_{HT} and L_{HT} is designed to take into account these parasitic elements to achieve optimal or near optimal harmonic impedances. In accordance with the teachings of the present disclosure, in operational conditions, a combination of C_{HT} and L_{HT} resonates to form an approximate short circuit (low impedance) at the second harmonic, while a combination of C_{HT}, L_{HT} and L_{S} resonates with C_{P} to present an approximate open circuit (high impedance) at the third harmonic. In other words, an optimal or near optimal implementation of the DA harmonic termination circuit 120 on the output of the DA 101 involves a careful consideration of the parasitic elements in the circuit.

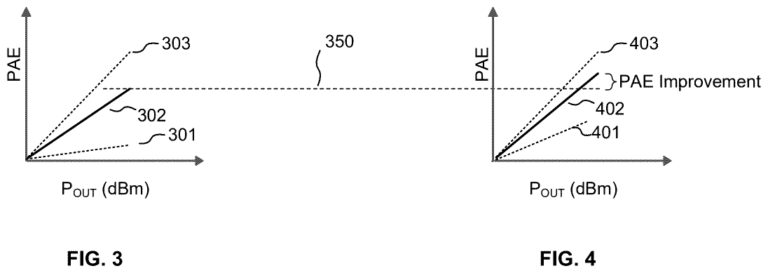

The embodiments of FIGS. 1-2 combine a driver amplifier (DA) and power amplifier (PA), typically implemented in semiconductor technologies such as GaAs, GaN, SOI/LDMOS, or SiGe. As described previously, the DA 101 operates in gain compression while the PA 102 operates in gain expansion, with the DA 101 biased at specific operating points to achieve both the desired gain compression characteristics and efficiency improvements due to the added DA harmonic termination circuit 120. This complementary behavior yields two key benefits: high output power (Pout) and Power Added Efficiency (PAE) from the PA stage, along with AM-AM and AM-PM distortion cancellation between the DA and PA stages. The distortion cancellation results in improved overall linearity of the two-stage PA 100. Implementation of harmonic termination on the DA 101 enhances the PAE performance of the power amplifier, particularly in certain frequency ranges. This is demonstrated in FIGS. 3 and 4, where PAE versus output power (Pout) characteristics are shown, with FIG. 3 displaying performance before inclusion of a DA harmonic termination circuit 120 in the two-stage PA system 100 of FIG. 1A, and FIG. 4 showing results after inclusion of a DA harmonic termination circuit 120 in the two-stage PA system 100 of FIG. 1A. Each figure contains three efficiency measurements: the DA efficiency (lines 301, 401), the PA efficiency (lines 303, 403), and the resultant overall effective efficiency (lines 302, 402). The implementation of harmonic termination on the DA side increases the slope of line 401 compared to line 301, indicating improved DA efficiency. This improvement results in a higher overall PAE, as shown by line 402 exceeding the previous maximum threshold (represented by line 350) achieved before implementing the DA harmonic termination circuit 120.

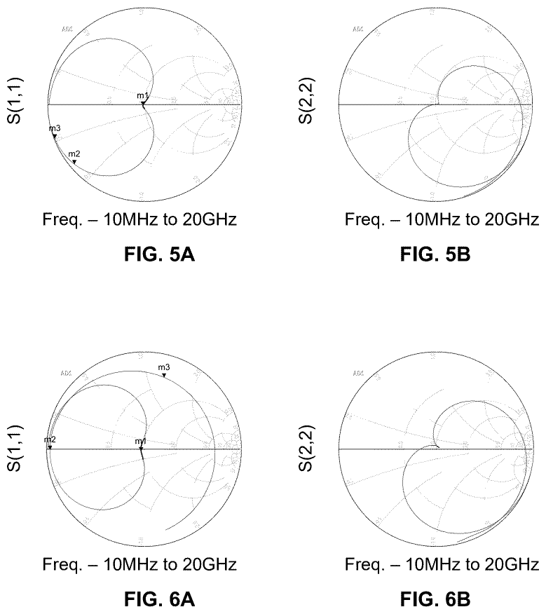

FIGS. 5A-5B show Smith chart plots characterizing the interstage matching network 104 without the inclusion of the DA harmonic termination circuit 120 on the output of the DA 101, within a frequency range of 10 MHz to 20 GHz. FIG. 5A shows parameter S(1,1) looking into the matching network from the DA side, while FIG. 5B shows parameter S(2,2) looking back from the PA input. In this configuration, while the fundamental frequency is well matched, the second and third harmonic impedances are not specifically controlled.

FIGS. 6A-6B show corresponding Smith chart plots characterizing the interstage matching network 104 with the inclusion of the DA harmonic termination circuit 120 on the output of the DA 101, within a frequency range of 10 MHz to 20 GHz. The key difference compared to FIGS. 5A and 5B is evident in the positioning of the second harmonic (low impedance) and third harmonic (high impedance) points on the Smith charts of FIGS. 6A and 6B, demonstrating beneficial harmonic termination characteristics for the DA 101.

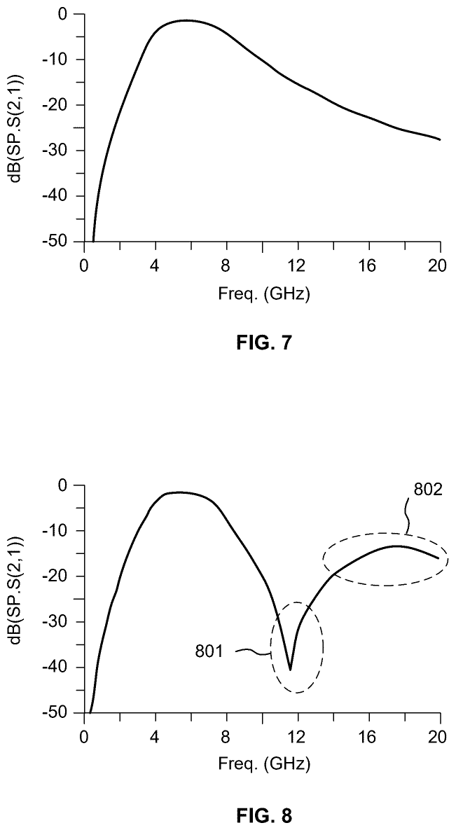

FIG. 7 is a graph showing the frequency response characteristics (S21) of the interstage matching network 104 without the inclusion of the DA harmonic termination circuit 120 on the output of the DA (101). FIG. 7 shows a generally monotonic decrease in response with increasing frequency. In contrast, FIG. 8 is a graph showing the frequency response characteristics (S21) of the interstage matching network 104 with the inclusion of the DA harmonic termination circuit 120 on the output of the DA 101. FIG. 8 shows a modified frequency response featuring a distinct notch 801 at the second harmonic frequency (around 11 GHz in this example), and a peak 802 at the third harmonic frequency (around 16 GHz in this example). This response shape is characteristic of the benefits provided by the DA harmonic termination circuit 120 coupled to the DA 101.

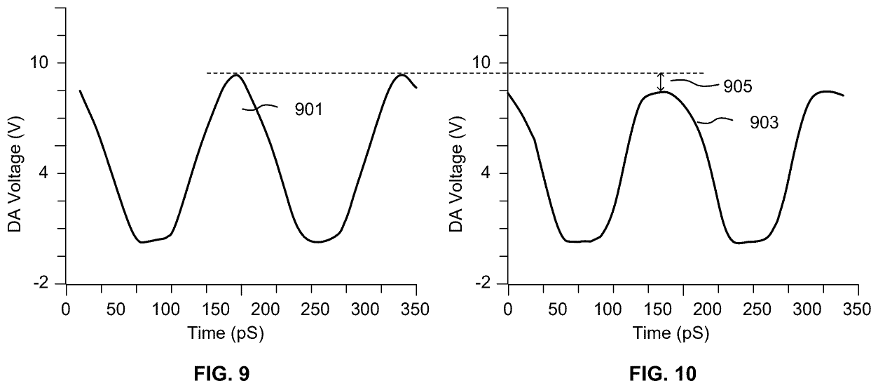

FIG. 9 is a graph showing the voltage waveform 901 measured at the collector of the DA transistor implemented in one embodiment of an exemplary two-stage PA system 100 that lacks a DA harmonic termination circuit 120. The waveform 901 exhibits close to sinusoidal characteristics with relatively high peak voltages. In comparison, FIG. 10 a graph showing a modified voltage waveform 903 measured at the collector of the DA transistor implemented in one embodiment of an exemplary two-stage PA system 100 that includes a DA harmonic termination circuit 120. FIG. 10 shows that the modified voltage waveform 903 displays a more-squared shape and reduced peak voltage levels, as indicated by distance 905 compared to the voltage waveform 901 of FIG. 9. This waveform shaping reduces voltage stress on the device, improving reliability and device longevity. This more-squared waveform characteristic is valuable for modern semiconductor technologies with lower breakdown voltages, as it effectively reduces peak voltage stress that could otherwise compromise long-term device reliability.

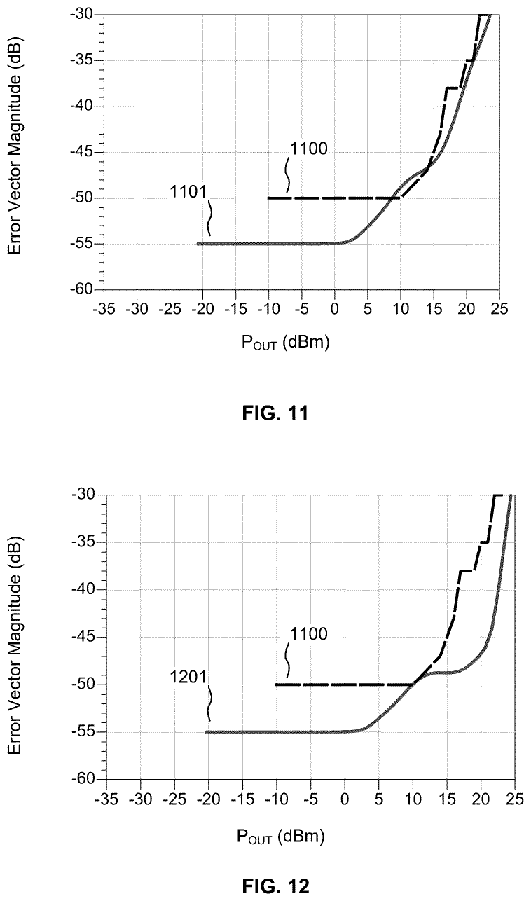

FIG. 11 is a graph of Error Vector Magnitude (EVM) performance versus power output P_{OUT} without inclusion of a DA harmonic termination circuit 120 on the output of a DA 101. The EVM serves here as a unified representation of the combined AM-AM, AM-PM, and overall PAE performance metrics. The dashed line 1100 represents a specification limit (e.g., a customer specification), while trace 1101 shows the measured EVM. FIG. 12 is a graph of Error Vector Magnitude (EVM) performance versus power output P_{OUT} with inclusion of a DA harmonic termination circuit on the output of a DA. Trace 1201 demonstrates maintained or improved linearity compared to the non-terminated case, while not only fully meeting the specification limit line 1100 but exceeding the specification limit line 1100 with a higher/improved margin. This confirms that the efficiency improvements of embodiments of the present invention are achieved without compromising linearity performance.

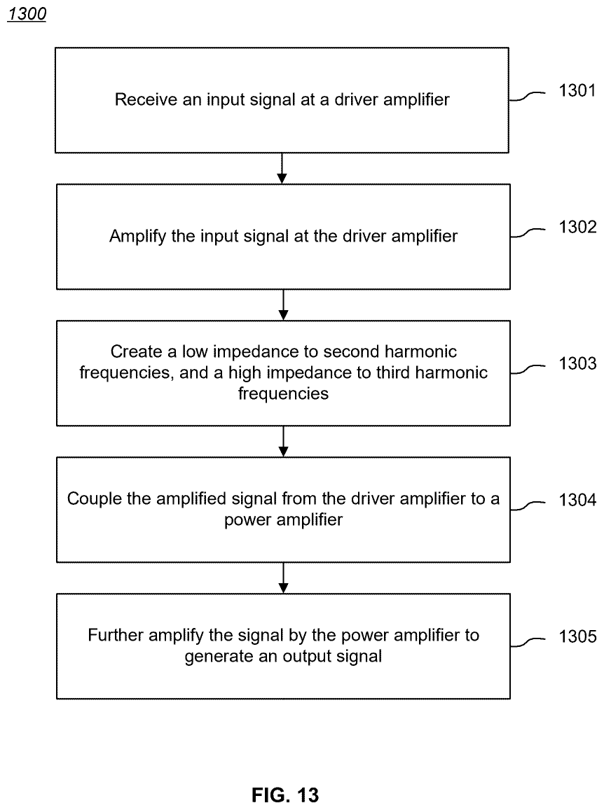

FIG. 13 shows an exemplary flowchart illustrating a method of PAE improvement in multi-stage amplifier systems according to an embodiment of the present disclosure. The illustrated method includes:
Receiving an input signal at a driver amplifier of the system, step 1301.
Amplifying the received input signal at the driver amplifier, step 1302.
Forming a low impedance to second harmonic frequencies, and high impedance to third harmonic frequencies, e.g., by using a harmonic termination at the output of the driver amplifier, step 1303.
Coupling the amplified signal from the driver amplifier to a power amplifier, step 1304.
Amplifying the signal at the power amplifier to generate an output signal, step 1305.

Implementation of harmonic termination on the DA as disclosed provides several benefits:
Improved Power Added Efficiency: measurements indicate PAE improvements ranging from 0.5% to 1.3% across various operating conditions. This enhancement in PAE is significant as it reduces current draw, leading to lower power consumption. By way of example, improvements were demonstrated by the inventors in a 5GHz-6GHz WiFi CPE application, showing particular effectiveness at these higher frequencies. As a result, a DA harmonic termination circuit enables the use of smaller batteries or extends a battery's life cycle.
Peak Voltage Reduction: a reduced peak voltage waveform that reduces stress on the driver transistor.
Enhanced Reliability: lower peak voltages improve long-term reliability especially for devices with low breakdown voltage.
Maintained or Improved Linearity: EVM measurements show no degradation in linearity.

While illustrated with a differential PA stage, the disclosed teachings are equally applicable to single-ended architectures. The described circuits and methods can also be extended to cascaded multi-stage amplifiers with three or more stages. Both DA and PA stages can be implemented as single-ended or differential multi-stage configurations. In multi-stage configurations of the DA, the disclosed DA harmonic termination circuitry may be implemented for one or more stages.

Implementation of harmonic termination techniques in power amplifier design presents significantly different challenges between power stages and driver stages. While harmonic termination has been successfully implemented in power stages, its application to driver stages requires overcoming several different technical hurdles. A key challenge arises from the inherent device sizing differences between driver and power amplifiers. Driver amplifiers typically employ smaller device sizes to optimize for gain and linearity, resulting in substantially lower parasitic output capacitance C_{P} values. This difference in parasitic capacitance has implications for harmonic termination implementation. The lower C_{P} values in driver amplifiers requires larger inductance values in the harmonic termination network to achieve the desired resonance conditions. This relationship may become problematic at lower frequencies. As an example, at 2.6 GHz, the required harmonic termination inductor value increases from 0.13 nH (at 5.6 GHz) to approximately 0.53 nH. The quality factor limitations of such larger inductors, particularly when implemented on-chip (i.e., as part of an IC), introduce losses that can negate the potential efficiency improvements from harmonic termination.

Implementation of the disclosed circuits and methods becomes more practical when specific conditions align, such as the following:
At higher operating frequencies (typically above 5 GHz), the smaller required inductance values achieve better quality factors, improving overall performance.
The insertion loss characteristics of the interstage matching network require careful consideration due to multiple competing factors. While the addition of DA harmonic termination components improves efficiency through better waveform shaping, these same components introduce losses in the fundamental signal path. The design involves balancing the efficiency gains from DA harmonic termination against the additional insertion loss from the DA termination components. At higher frequencies where smaller component values can be used, this tradeoff typically favors implementation of DA harmonic termination. However, at lower frequencies where larger inductance values are needed, the increased insertion loss can outweigh the potential efficiency improvements. This creates an optimization problem where component values must be selected to maximize harmonic termination effectiveness while minimizing impact on the fundamental signal path.
The effectiveness of driver amplifier harmonic termination exhibits technology dependence. Different semiconductor technologies provide different device parasitic values, with parallel capacitance C_{P} values being particularly critical. For example, in tested HBT implementations at 5.6 GHz, typical C_{P} values in some embodiments of the present disclosure were approximately 2.3 pF for the PA stage and 1.16 pF for the DA stage. These higher C_{P} values enabled practical implementation with inductance values, in some cases, around 0.13nH. Technologies that provide higher parallel capacitance C_{P} values can be advantageous for DA harmonic termination implementation as they allow for smaller inductance values in the harmonic trap design. This relationship between C_{P} and required inductance values becomes a key consideration in selecting appropriate semiconductor technology for implementing driver amplifier harmonic termination circuitry.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

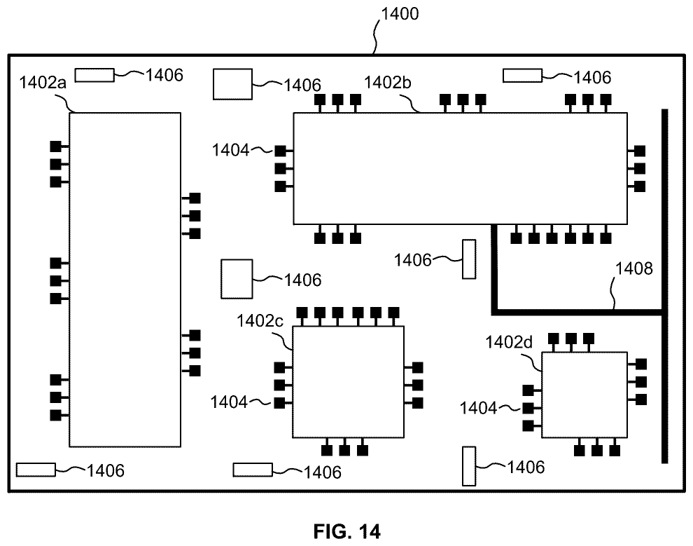

As one example of further integration of embodiments of the present invention with other components, FIG. 14 is a top plan view of a substrate 1400 that may be, for example, a printed circuit board or chip module substrate (e.g., a thin-film tile). In the illustrated example, the substrate 1400 includes multiple ICs 1402a-1402d having terminal pads 1404 which would be interconnected by conductive vias and/or traces on and/or within the substrate 1400 or on the opposite (back) surface of the substrate 1400 (to avoid clutter, the surface conductive traces are not shown and not all terminal pads are labelled). The ICs 1402a-1402d may embody, for example, signal switches, active and/or passive filters, amplifiers (including one or more LNAs), and other circuitry. For example, IC 1402b may incorporate one or more instances of a power amplifier system in accordance with the teaching of this disclosure.

The substrate 1400 may also include one or more passive devices 1406 embedded in, formed on, and/or affixed to the substrate 1400. While shown as generic rectangles, the passive devices 1406 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1400 to other passive devices 1406 and/or the individual ICs 1402a-1402d.

The front or back surface of the substrate 1400 may be used as a location for the formation of other structures. For example, one or more antennae may be formed on or affixed to the front or back surface of the substrate 1400; one example of a front-surface antenna 1408 is shown, coupled to an IC die 1402b, which may include RF front-end circuitry. Thus, by including one or more antennae on the substrate 1400, a complete radio may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

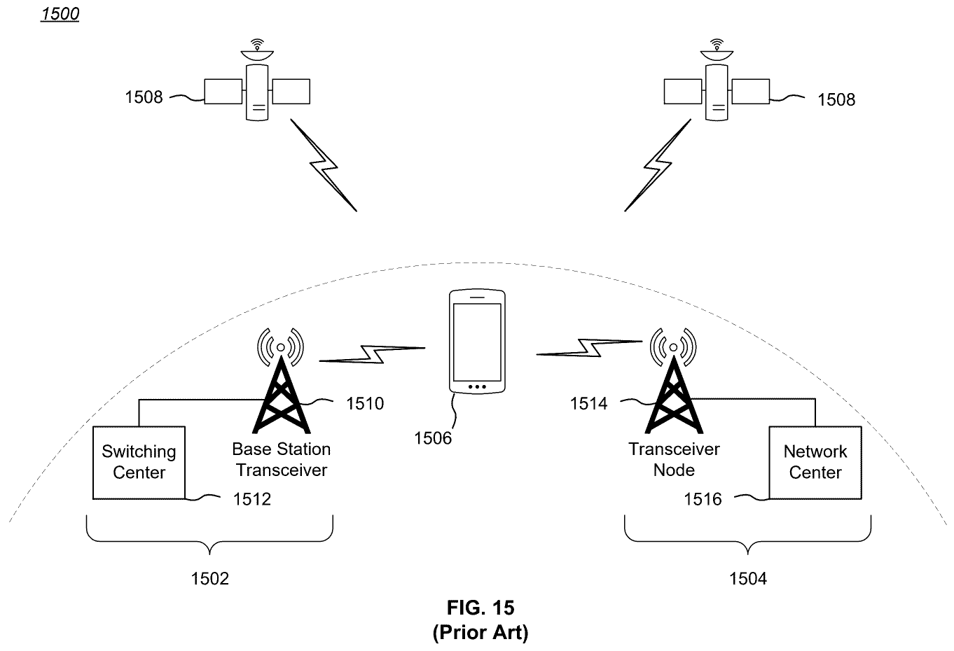

As an example of wireless RF system usage, FIG. 15 illustrates a prior art wireless communication environment 1500 including different wireless communication systems 1502 and 1504, and which may include one or more mobile wireless devices 1506. A wireless device 1506 may be a cellular phone, a wireless-enabled computer or tablet, or some other wireless communication unit or device. A wireless device 1506 may also be referred to as a mobile station, user equipment, an access terminal, or some other terminology known in the telecommunications industry.

A wireless device 1506 may be capable of communicating with multiple wireless communication systems 1502, 1504 using one or more of telecommunication protocols such as the protocols noted above. A wireless device 1506 also may be capable of communicating with one or more satellites 1508, such as navigation satellites (e.g., GPS) and/or telecommunication satellites. The wireless device 1506 may be equipped with multiple antennas, externally and/or internally, for operation on different frequencies and/or to provide diversity against deleterious path effects such as fading and multi-path interference.

The wireless communication system 1502 may be, for example, a CDMA-based system that includes one or more base station transceivers (BSTs) 1510 and at least one switching center (SC) 1512. Each BST 1510 provides over-the-air RF communication for wireless devices 1506 within its coverage area. The SC 1512 couples to one or more BSTs 1510 in the wireless system 1502 and provides coordination and control for those BSTs 1510.

The wireless communication system 1504 may be, for example, a TDMA-based system that includes one or more transceiver nodes 1514 and a network center (NC) 1516. Each transceiver node 1514 provides over-the-air RF communication for wireless devices 1506 within its coverage area. The NC 1516 couples to one or more transceiver nodes 1514 in the wireless system 1504 and provides coordination and control for those transceiver nodes 1514.

In general, each BST 1510 and transceiver node 1514 is a fixed station that provides communication coverage for wireless devices 1506, and may also be referred to as base stations or some other terminology known in the telecommunications industry. The SC 1512 and the NC 1516 are network entities that provide coordination and control for the base stations and may also be referred to by other terminologies known in the telecommunications industry.

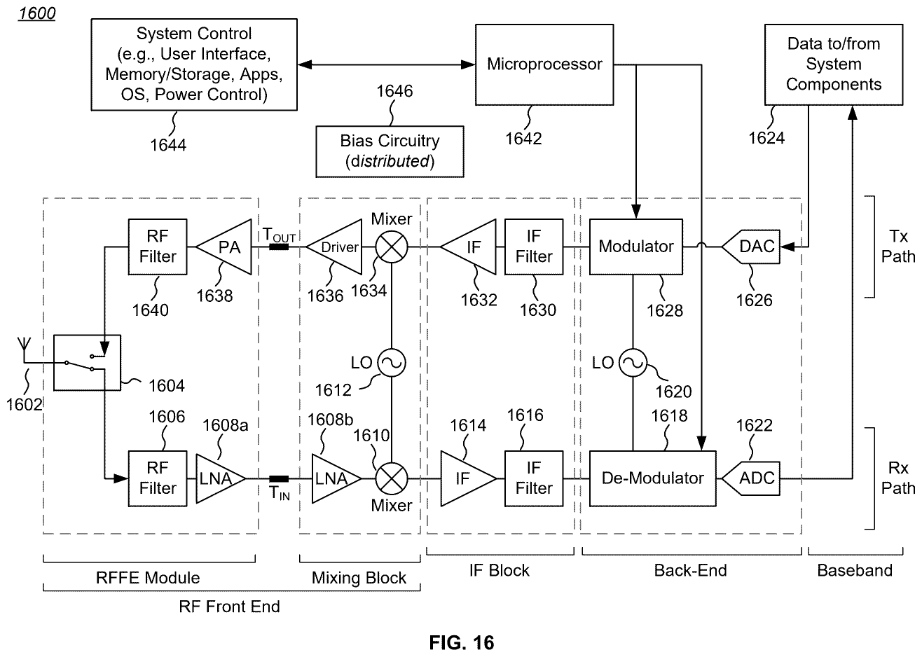

An important aspect of any wireless system, including the systems shown in FIG. 15, is in the details of how the component elements of the system perform. FIG. 16 is a block diagram of a transceiver 1600 that might be used in a wireless device, such as a cellular telephone, and which may beneficially incorporate an embodiment of the present invention for improved performance. As illustrated, the transceiver 1600 includes a mix of RF analog circuitry for directly conveying and/or transforming signals on an RF signal path, non-RF analog circuity for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines T_{IN} and T_{OUT} (e.g., microstrips, co-planar waveguides, or an equivalent structure or circuit), either or both of which may have, for example, a 50 Ω impedance.

The receiver path Rx receives over-the-air RF signals through at least one antenna 1602 and a switching unit 1604, which may be implemented with active switching devices (e.g., field effect transistors or FETs) and/or with passive devices that implement frequency-domain multiplexing, such as a diplexer or duplexer. An RF filter 1606 passes desired received RF signals to at least one low noise amplifier (LNA) 1608a, the output of which is coupled from the RFFE Module to at least one LNA 1608b in the Mixing Block (through transmission line T_{IN} in this example). The LNA(s) 1608b may provide buffering, input matching, and reverse isolation. In some embodiments, the LNA(s) 1608a and 1608b may be a single LNA.

The output of the LNA(s) 1608b is combined in a corresponding mixer 1610 with the output of a first local oscillator LO 1612 to produce an IF signal. The IF signal may be amplified by an IF amplifier 1614 and subjected to an IF filter 1616 before being applied to a demodulator 1618, which may be coupled to a second local oscillator LO 1620. The demodulated output of the demodulator 1618 is transformed to a digital signal by an analog-to-digital converter (ADC) 1622 and provided to one or more system circuits 1624 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system circuits 1624 is transformed to an analog signal by a digital-to-analog converter (DAC) 1626, the output of which is applied to a modulator 1628, which also may be coupled to the second local oscillator LO 1620. The modulated output of the modulator 1628 may be subjected to an IF filter 1630 before being amplified by an IF amplifier 1632. The output of the IF amplifier 1632 is then combined in a mixer 1634 with the output of the first local oscillator LO 1612 to produce an RF signal. The RF signal may be amplified by a driver 1636, the output of which is coupled to a power amplifier (PA) 1638 (through transmission line T_{OUT} in this example). The amplified RF signal may be coupled to an RF filter 1640, the output of which is coupled to at least one antenna 1602 through the switching unit 1604.

The operation of the transceiver 1600 is controlled by a microprocessor 1642 in known fashion, which interacts with system control circuits or components 1644 (e.g., user interfaces, memory/storage devices, application programs, operating system software, power control, etc.). In addition, the transceiver 1600 will generally include other circuitry, such as bias circuitry 1646 (which may be distributed throughout the transceiver 1600 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some circuits and/or components of the transceiver 1600 may be positioned in a different order (e.g., filters) or omitted. Other components and/or circuits can be (and often are) added, such as (by way of example only) additional filters, impedance matching networks, variable phase shifters/attenuators, power dividers, etc

The term “MOSFET”, as used in this disclosure, includes any field effect transistor (FET) having an insulated gate whose voltage or charge level determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or direct ions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A power amplifier system including:
a) a driver amplifier;
b) a power amplifier coupled to an output of the driver amplifier, and
c) a first harmonic termination circuit coupled to the output of the driver amplifier,
wherein the first harmonic termination circuit is configured to provide a low impedance at second harmonic frequencies and a high impedance at third harmonic frequencies based on parasitic elements of the driver amplifier.

2. The power amplifier system of claim 1, wherein the output of the driver amplifier is coupled to the power amplifier via an interstage impedance matching network.

3. The power amplifier system of claim 2, wherein the parasitic elements include a parallel output capacitance of the driver amplifier, and a parasitic series inductance associated with one or more conductors connecting the driver amplifier to the interstage impedance matching network.

4. The power amplifier system of claim 1, further including a second harmonic termination circuit coupled to an output of the power amplifier.

5. The power amplifier system of claim 1, wherein the driver amplifier is configured to operate in gain compression, and the power amplifier is configured to operate in gain expansion.

6. The power amplifier system of claim 1, wherein the power amplifier includes a differential amplifier configuration, and the interstage impedance matching network includes a transformer configured to convert between single-ended and differential signals.

7. The power amplifier system of claim 6, wherein the transformer includes a) a primary winding coupled to the driver amplifier output, and b) a center-tapped secondary winding coupled to differential inputs of the power amplifier.

8. The power amplifier system of claim 1, wherein the first harmonic termination circuit includes an inductor and a capacitor coupled in series.

9. The power amplifier of claim 8, wherein the value of the inductor and capacitor are selected such that:
a) the first harmonic termination circuit resonates at the second harmonic frequencies to form a low impedance, and
b) a combination of the first harmonic termination circuit and the series parasitic inductance resonates with the parallel output capacitor at the third harmonic frequencies.

10. The power amplifier system of claim 1, wherein the driver amplifier includes a single or differential configuration, and the power amplifier includes a single-ended or differential configuration.

11. The power amplifier system of claim 1, wherein the driver amplifier includes one or more driver stages.

12. The power amplifier system of claim 11, wherein at least one driver stage of the one or more driver stages includes an additional harmonic termination circuit coupled to an output of the at least one driver stage, the output of at least one driver stage positioned upstream of the output of the driver amplifier.

13. The power amplifier system of claim 1, further including an input impedance matching circuit coupled to an input of the driver amplifier and an output impedance matching circuit coupled to an output of the power amplifier.

14. The power amplifier system of claim 1, wherein the driver amplifier is configured to operate at a first bias point to achieve gain compression, and the power amplifier is configured to operate at a second bias point to achieve gain expansion, wherein a combination of gain compression and expansion results in amplitude modulation to amplitude modulation (AM-AM) and amplitude modulation to phase modulation (AM-PM) distortion cancellation.

15. The power amplifier system of claim 1, wherein the driver amplifier and power amplifier are implemented in a semiconductor technology selected from the group consisting of: GaAs, GaN, SOI, LDMOS, and SiGe.

16. The power amplifier system of claim 1, implemented in a wireless communication device selected from the group consisting of: a consumer premises equipment (CPE) device, a base station, and a mobile device.

17. A wireless communication device including a radio frequency front end module including: a multi-stage power amplifier including a) a driver amplifier, b) a power amplifier coupled to an output of the driver amplifier; and c) a driver harmonic termination circuit coupled to the output of the driver amplifier, wherein the driver harmonic termination circuit is configured to provide a low impedance at second harmonic frequencies and a high impedance at third harmonic frequencies based on parasitic elements of the driver amplifier.

18. A power amplifier system including a plurality of cascaded amplifier stages including a) at least one driver stage, b) a power stage, and c) a plurality of harmonic termination circuits, each coupled to an output of a respective amplifier stage, wherein each harmonic termination circuit is configured to provide stage-specific harmonic impedances based on parasitic elements of its respective amplifier stage.

19.-28. (canceled)
